(19) United States
(12) Patent Application Publication
(10) Pub. No.: US 2012/0217526 A1
(43) Pub. Date: Aug. 30, 2012

(54) CHIP LED

(75) Inventor: Masao KUMURA, Tokyo (JP)

(73) Assignee: E&E Japan Co., Ltd., Shinjuku-ku (JP)

(21) Appl. No.: 13/396,194

(22) Filed: Feb. 14, 2012

(30) Foreign Application Priority Data
Feb. 24, 2011 (JP) 2011-028733

(51) Int. Cl. H01L 33/40

(52) U.S. Cl. 257/98; 257/E33.061

(57) ABSTRACT

The chip LED includes a plurality of semiconductor chips at least one of which is a light-emitting element; a recess formed on the packaging substrate having a rear-side metallic layer on the rear-side thereof, and a metallic layer formed on the bottom surface and inner wall surface of the recess; the light-emitting element being die-bonded to the metallic layer formed on the bottom surface of the recess and being wire-bonded to a wiring pattern deposited on the surface of the packaging substrate; and the metallic layer formed on the bottom surface of the recess being electrically conducted to the rear-side metallic layer formed on the rear side of the packaging substrate.

### BACKGROUND OF THE INVENTION

1. Field of the Invention

Generally, the present invention relates to a light-emitting diode (referred to as LED) or any other similar device. More particularly, the present invention relates to the chip LED that employs the glass epoxy resin-based substrate as the packaging or mounting substrate.

2. Description of the Prior Art

The chip LED represents the light-emitting diode that has the high productivity and may be fabricated at low costs. In the conventional prior art, it has been used mainly as the display element that requires less power. In this case, the electric current that flows through those conventional chip LEDs is mostly in the order of 20 mA.

For the recent years and in most cases, this type of LED has been used for the liquid crystal display (LCD) backlight or lighting. It is noted, however, that a relatively large amount of electric current flows through the type of LED that is used for the backlight or lighting of the LCD television, and therefore the conventional type of LED has not been used for these backlight or lighting purposes. This is because the conventional chip LED has the problems in which when the relatively large amount of current flows through the chip LED, the package on which it is mounted has the large thermal resistance that causes the high temperature heating to be produced, thereby affecting the light-emitting efficiency adversely and discoloring the resin that is based on the package, the chip LED may have the short life time, and the like.

It is also noted that the chip LED emits a white color light that is mainly used for the backlight or lighting purpose and that in most cases, the white color light can be generated by covering the blue color emitting element with the resin containing any phosphor material. For this purpose, it is usual that the PLCC-type package that includes a reflective case having its lead frame being injection-molded is used or ceramics package, but the package on which the chip LED is implemented has not been used because of its poor heat dissipation, etc., although this package has the high productivity and may be fabricated at low costs.

The following is the list of the prior publications that are associated with the present invention and are cited appropriately herein:

(1) Japanese patent application No. Show 62 (1987)-112333

(2) Japanese patent No. 2927279 publication

(3) Japanese patent No. 3900144 publication

### SUMMARY OF THE INVENTION

The conventional chip LED in general will be described below by referring to FIG. 1.

A packaging substrate 2 on which the chip LED is implemented is provided, which includes a glass epoxy resin-based substrate material 14 having a copper foil laminated on both the sides (front side and rear side) thereof and a through-hole made by drilling the substrate 2. The glass epoxy resin-based substrate material 14 includes a pattern that is preliminarily formed by plating the copper using the non-electrolysis process and a wiring pattern 9 that is then formed by plating the Cu+Ni+Au or Cu+Ni+Ag using the electrolysis or non-electrolysis process.

A light-emitting element 1 (which is referred hereinafter to as the LED chip) has the wiring pattern 9 on which it is die-bonded with a silver paste (not shown), it is then wire-bonded with a gold wire 10, and is finally transfer-molded with an epoxy resin 8.

For the conventional chip LED having the structure described above, most of the heat that is produced from the LED chip 1 is dissipated through the wiring pattern 9 made of the copper foil (plated with Cu+Ni+Au or Cu+Ni+Ag). The copper foil, which is currently used and includes the copper foil-base metallic layer as well, is so thin (usually 36 μm) that its heat dissipating efficiency is not so good.

It is noted, however, that the white color light-emitting chip LED, which is fabricated by sealing the blue color-emitting chip with the epoxy resin containing any phosphor material, presents some problems in which the epoxy resin may be changed to the yellow color when it is exposed to the short wavelength light, and the light output may be decreased.

For those white color light emitting chips that produce the less light output, there is no problem such as those described above because those chips are not deteriorated so much. As the light output becomes greater, however, the deterioration may occur very quickly.

There is also a method that eliminates the above problems by covering the front surface of the chip 1 with the silicone resin prior to covering it with the epoxy resin. When this method is performed for the chip LED having the conventional structure, the silicone resin may be flowing in such a manner that it may be expanded over the surface of the chip LED. This may weaken the bonding ability of the epoxy resin. For this reason, this method has not been used with those chip LEDs.

It is an object of the present invention to provide a chip LED that eliminates the problems associated with the conventional chip LEDs and described above and can be used for the backlight purposes on the LCD television or lighting.

The invention as defined in claim 1 comprises a chip LED having more than at least one semiconductor chips mounted thereon, wherein the chip LED includes:

more than one semiconductor chips at least one of which is a light-emitting element;

a packaging substrate including a wiring pattern formed on the front side thereof, said packaging substrate having a rear-side metallic layer formed on the rear side thereof and having a recess formed from the front side toward the rear side, said recess having a metallic layer formed on the bottom surface and inner wall surface thereof;

said light-emitting element being die-bonded to the metallic layer formed on the bottom surface of said recess and being wire-bonded to the wiring pattern formed on the front side of the packaging substrate; and

the metallic layer formed on the bottom surface of said recess being electrically conducted to the rear-side metallic layer formed on the rear side of the packaging substrate, said rear-side metallic layer providing the heat dissipating path through which the heat produced by said light-emitting element can be dissipated.

The invention as defined in claim 2 includes the chip LED according to claim 1, wherein said recess has the depth that is greater than the thickness of said light-emitting element.

The invention as defined in claim 3 includes the chip LED according to claim 1 or 2, wherein said recess is filled with a silicone resin containing any phosphor material, the outside of said recess being covered by the epoxy resin.

The invention as defined in claim 4 includes the chip LED according to any one of claims 1, 2 and 3 and provides an LED module, wherein said LED module includes a metal substrate on which the chip LED is implemented by the soldering process, and a metal portion on said metal substrate to which said rear-side metallic layer is bonded by the soldering process at the same time.

The present invention has the advantage in that it is possible to provide a chip LED that can be used for the backlight or lighting purpose on the LCD television.

In addition, the present invention has the advantage in that it is possible to provide an LED that provides the high power and high light output by taking an advantage of the features of the high productivity and low cost provided by the chip LED.

Furthermore, the present invention has the advantage in that it is possible to provide an LED module that has the good heat dissipation and the high reliability with respect to the temperature cycle.

### BRIEF DESCRIPTION OF THE DRAWINGS

FIG. 1 is a schematic diagram illustrating the structure of the conventional prior art chip LED, in which (a) represents a schematic cross-sectional view and (b) represents a schematic plan view (referred to as the schematic plan view) although the sealing resin coating is omitted from the schematic plan view;

FIG. 2 is a flow diagram showing the steps (a) through (e) through which the packaging substrate may be fabricated for use with the present invention;

FIG. 3 is a schematic diagram illustrating the structure of the chip LED according to the present invention, in which (a) represents a schematic cross-sectional view and (b) represents a schematic plan view;

FIG. 4 is a schematic cross-sectional diagram illustrating the LED module according to the present invention with the chip LED of the present invention being bonded to the circuit substrate by the appropriate soldering process;

FIG. 5 is a schematic plan view illustrating the chip LED of the present invention with a rectangular chip being used on the elliptical-shape recess;

FIG. 6 is a schematic plan view illustrating the chip LED of the present invention with two chips being used on the elliptical-shape recess;

FIG. 7 is a schematic plan view illustrating the chip LED of the present invention with a square chip being used on the square-shape recess;

FIG. 8 is a schematic plan view illustrating the chip LED of the present invention with two chips, blue color and red color, being mounted on two recesses;

FIG. 9 is a circuit diagram showing the chip LED of the present invention including a plurality of diodes being formed in series on one chip and permitting Vf to be adjusted by the laser cut;

FIG. 10 is a schematic diagram that is provided for calculating the heat dissipation specifically for the conventional chip LED having the structure according to the prior art;

FIG. 11 is a schematic diagram illustrating the flow of the heat for the conventional chip LED having the structure according to the prior art; and

FIG. 12 is a schematic diagram illustrating the flow of the heat for the chip LED having the structure according to the present invention.

### BEST MODES OF EMBODYING THE INVENTION

The preferred embodiment of the present invention will now be described by referring to the accompanying drawings.

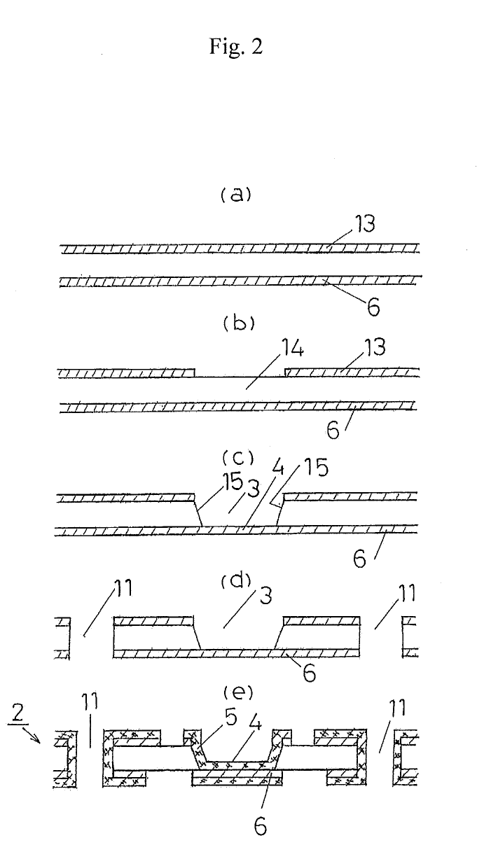

As shown in FIG. 2 (a), a substrate material 14 that is provided for use with the present invention is based on a glass epoxy resin that has a copper foil laminated on both the sides thereof (front side and rear side). The substrate material 14 includes a recess 3 that is formed in such a manner that it is extended toward a rear side metallic layer 6 deposited on the rear side of the substrate material 14 (FIG. 2 (c)).

The recess 3 includes a metallic layer 5 that is deposited on the bottom surface and inner wall surface thereof (FIG. 2 (e)). This metallic layer 5 may be deposited by the appropriate plating process, for example.

As a through-hole 11 is also required for the chip LED, it is more effective that this through-hole 11 should be provided at the same time as the metallic layer 5 is deposited on the bottom surface and inner wall surface of the recess 3 (FIG. 2 (e)).

Following the plating process for the metallic layer 5, the packaging substrate 2 that has a pattern formed by the photo-etching or like process is used for the chip LED.

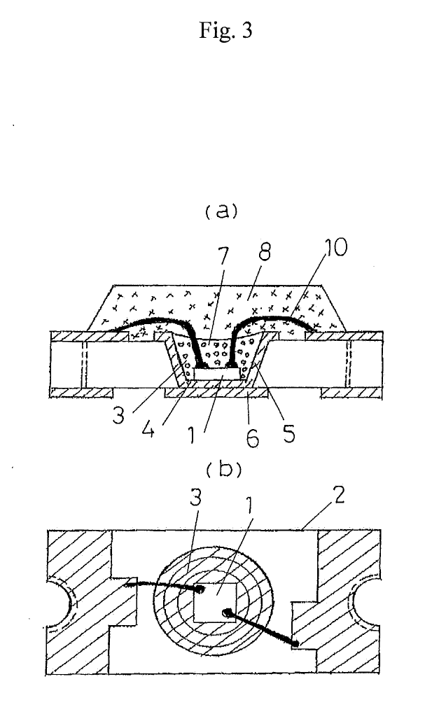

After this, an LED chip 1 is then die-bonded with a silver paste to the metallic layer 5 deposited on the bottom surface of the recess (FIG. 3 (a)). After the LED chip 1 is wire-bonded to the wiring pattern formed on the front side of the packaging substrate 2, it is sealed with the epoxy resin. The chip LED of the present invention is thus provided, as shown in FIG. 3 (a) and (b).

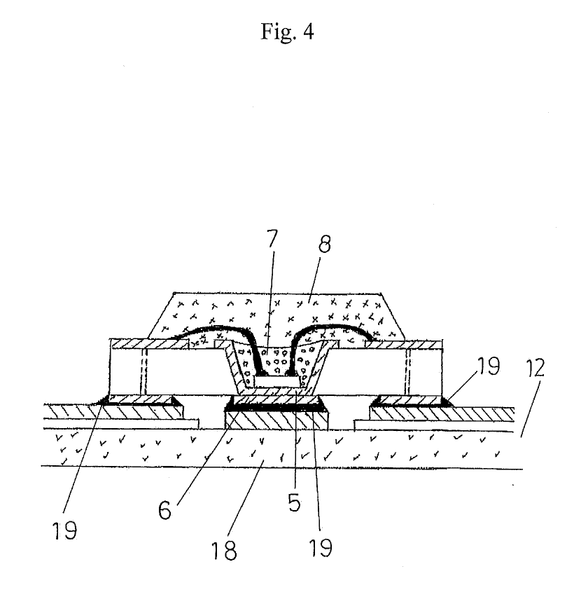

As shown in FIG. 3 (a) and (b), the chip LED of the present invention may be mounted on the circuit substrate 12 by soldering the rear-side metallic layer 6 to the circuit substrate 12. As shown in FIG. 4, the metallic layer 5 die-bonded to the LED chip 1 as well as the rear-side metallic layer 6 located on the rear side of the metallic layer 5 may thus be used for the heat dissipation. As this is described specifically, the rear-side metallic layer 6 provides the heat dissipating path for the heat produced in the LED chip 1. In this way, the heat produced in the LED chip 1 can be dissipated mainly through the rear-side metallic layer 6. This is the feature of the present invention. It may be appreciated from the above description that the chip LED of the present invention provides the heat dissipating effect that is equal to several ten times that of the prior art chip LED.

The problem of yellowing the resin that may be caused when a blue color chip is used may be removed by providing a recess 3 and then filling the recess 3 with the silicone resin 7 which is hard to be discolored by the short wavelength.

Although an example of the preferred embodiment of the present invention is now described by referring to the accompanying drawings, it should be understood that the present invention is not limited to the preferred embodiment of the present invention described above and the example of the embodiment to be described below. It should be appreciated, therefore, that various changes or modifications may be made without departing from the spirit and scope of the present invention as defined in the appended claims.

### Embodiment

Similarly to the prior art chip LED, the substrate material 14 which is based on the glass epoxy resin and has the copper foil laminated on both the sides (front side and rear side) thereof may be used (FIG. 2 (a)).

The copper foil 13 on the side (front side) on which the LED chip 1 is implemented may be bored by the photo-etching process (FIG. 2 (b)).

The glass epoxy resin-based substrate material 14 that is now bored and exposed may be shaved by the laser beams while the copper foil 13 is masked. The recess 3 may thus be provided (FIG. 2 (c)).

Considering the light reflectivity of the LED, it is desirable that the recess 3 should have the depth that is greater than the thickness of the LED chip 1 and should be formed to the shape that includes a slant expanding toward the opening on the copper foil 13.

It is important that the bottom surface 4 of the recess 3 should be extended so that it can reach the copper foil on the rear side of the substrate material 14, that is, the rear-side metallic layer 6.

The front side (the upper side in the drawing) of the rear-side metallic layer 6 on the bottom surface 4 of the recess 3 may be cleaned by the plasma process, and then the front side (the upper side in the drawing) of the rear-side metallic layer 6 may be smoothened as required. As the bottom surface of the recess 3 presents the uneven surface of the copper foil that has been electrolyzed for forming the rear-side metallic layer 6, this uneven surface may cause a problem at the time of the die-bonding process. This problem may be eliminated by making this uneven copper foil surface smooth by means of the “Kirinsu” treatment or like process. “Kirinsu” treatment is a kind of the treatment which smoothes the surface of uneven copper using acid.

Then, a bore for the through-hole 11 may be provided by the drilling process (FIG. 2 (d)), and the lateral side of the through-hole 11 and the inner wall surface 15 formed on the bottom surface 4 and slant of the recess 3 may be plated.

As described above, it is desirable that the light reflectivity of the LED should be considered for the recess 3, and it is desirable, therefore, that the metallic layer 5 formed on the inner wall surface 15 by the plating process should be formed from any metal that provides the good light reflectivity.

For example, the surface of the inner wall surface 15 formed on the slant of the recess 3 may be silver-plated. This may provide the better reflectivity for the short wavelength of such as the blue color, thus improving the efficiency with which the light can be generated.

Next, a pattern may be deposited by the photo-etching process, and may then be plated with Cu+Ni+Au or Cu+Ni+Ag.

Following the steps described above, the packaging substrate 2 that may be used with the present invention is thus completed as shown in FIG. 2 (e)).

It may be understood that the Ag plate provides the better light reflectivity for the blue color light. Accordingly, the surface should be plated with Ag rather than Au so that the better light emitting efficiency can be obtained. Note, however, that Ag is more likely to cause the migration, and may be changed to the black color by reacting to the sulfurized gas, causing the reflectivity to be lowered remarkably. It is thus necessary that this respect should be taken into consideration.

For the migration that is caused by Ag, it may be improved by adding a small amount of Pd at the time of the silver plating process. For the sulfurization that occurs prior to the usage, it may be improved by using an aluminum foil bag that contains a dry nitrogen gas being sealed therein. For the sulfurization that occurs after the usage, it may be improved by employing the epoxy resin having a low gas transmission rate as the sealing resin

It is also possible to use Al instead of Ag. Al may be deposited by the vapor deposition, which permits the use of the sputtering process. In this case, it is possible either to perform the Al vapor deposition after the Cu—Ni plating rather than the Cu—Ni—Au plating described above, or to perform the Ti—Al vapor deposition after the Cu plating.

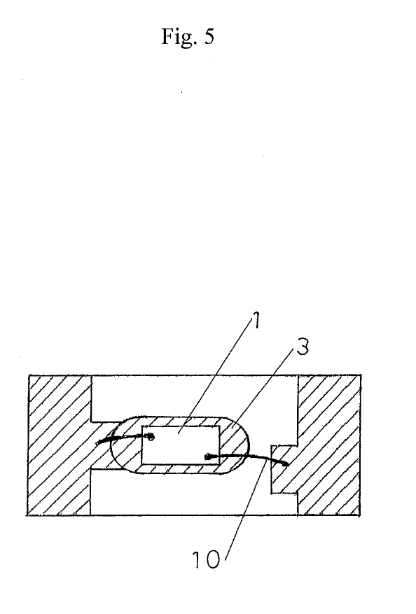

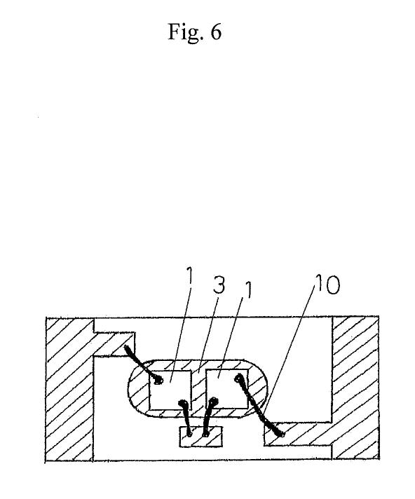

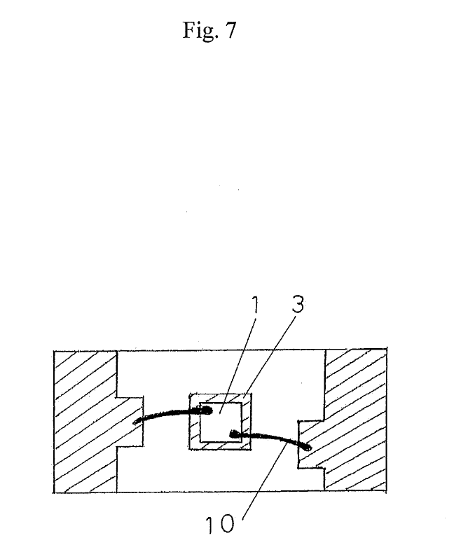

It may be appreciated from the above description that the recess 3 may be formed into the various shapes by forming the recess 3 by exposing it the laser beams. As an example, FIG. 3 shows that the square-shape LED chip 1 may be mounted on the circular-shape recess 3 as seen from the plan view. As another example, FIG. 5 shows that the rectangular-shape LED chip 1 may be mounted on the elliptical-shape recess 3 as seen from the plan view. As still another example, FIG. 6 shows that two rectangular-shape LED chips 1 may be mounted on the elliptical-shape recess 3 as seen from the plan view. In order to the reduce the size, as shown in FIG. 7, it is also possible to provide the square recess 3 as seen from the plan view, on which the square-shape LED chip 1 may be implemented.

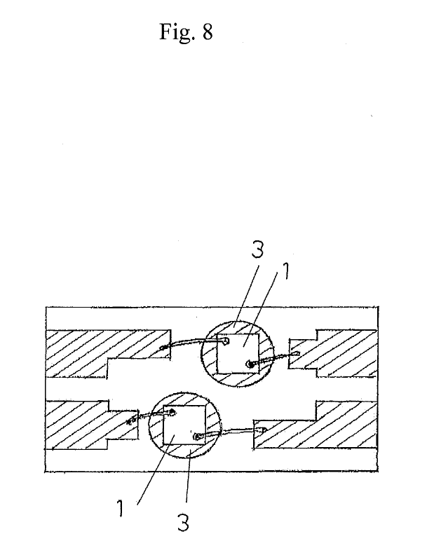

FIG. 8 shows an example of the chip LED 1 in which the 2 chips in 1 package contains the blue-color LED chip 1 on which a phosphor material is placed and the blue-color LED chip 1 on which the red-color LED chip 1′ is placed. For the warm color lighting, the yellow color and red color phosphor materials have been placed on the blue-color chip in the prior art. It is noted, however, that the red color phosphor material is costly, and its light emitting efficiency is not so good. As shown in FIG. 8, the light emitting efficiency may be enhanced by using the red-color LED chip instead of the red color phosphor material. Specifically, FIG. 8 shows an example of the structure in which the blue color LED chip 1 is covered by the phosphor material while the red-color LED chip 1′ is not covered by the phosphor material.

In the above case, there are two methods, for example. One method is to allow the blue color LED chip to provide the white colors by adding the yellow phosphor material, and further to allow the red-color LED chip to provide the warm colors. The other method is to allow the green phosphor material to be added on the blue color LED chip, and further to allow the red-color LED chip to provide the white colors or warm colors.

By using the two chips, blue color and red color, it is possible to vary the currents flowing through those chips, thereby varying the color temperature of the lighting.

Although it may be possible to provide the red color on the area where the recess 3 does not exist, however, it will nevertheless be possible to improve the heat dissipation, thereby preventing the rise in the temperature of the red color if the red color is provided on the recess 3.

As compared with the blue color, the red color presents a problem in that its light-emitting efficiency becomes worse at the high temperatures and the color balance is easier to collapse. According to the present invention, however, this problem can be eliminated by preventing the rise in the temperature of the red color.

Although FIGS. 3 through 8 illustrate the examples in which the present invention may be applied; it is of course that the electrostatic situation can be prevented by implementing a Zener diode within the chip LED as required.

Lighting may be provided by AC 100V or 200V power supply. The forward voltage (referred to as VO of the LED is about 3V for the blue color and about 2V for the red color. In order to increase the power efficiency, it is necessary to connect the LEDs in series, thereby increasing the value of Vf.

The value of Vf may be increased by depositing numerous diodes within one chip. For example, the HV-LED manufactured by the Epistar corporation in Taiwan contains numerous LEDs deposited and connected in series within one chip, thus providing Vf of 45V.

In this way, the power supply portion for the LED lighting can be deposited in the small space.

For the blue color chip in the InGaN family, furthermore, it is recognized that the variations in the value of Vf will become large. For the article of one chip 45V that is commercially available, for example, it contains 14 diodes that are connected in series. When those 14 diodes are connected in series, they will provide the value of Vf that may be varied largely. If the difference in the value of Vf is great, it may also cause the current flow through those diodes to be varied, causing the resulting light intensity to be varied largely accordingly.

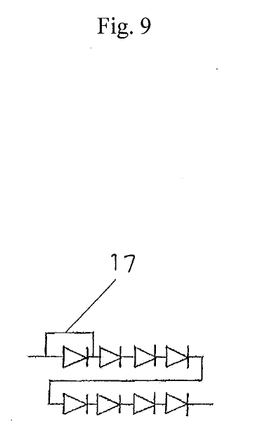

In order to mitigate the problem described above, one diode is previously provided as shown in FIG. 9, and this diode may be short-circuited by a wire 17 across the diode. The wire 17 that has short-circuited the diode in this way may be cut by means of the laser trimming process or the like. Then, Vf may be increased by the value of Vf that is equal to one diode, and the variations in Vf may thus be regulated.

The chip LED that is offered by the present invention may be used with LCD television or for the lighting. As shown in FIG. 4, this chip LED may be bonded to the circuit substrate 12 by means of a solder 19. It should be appreciated that the circuit substrate 12 may include a metal substrate 18 which is based on aluminum or copper.

The soldering may be performed by the reflow process using the solder paste. It should be appreciated, however, that while the chip LED of the present invention may be implemented on the metal substrate 18 by means of the soldering process, the read-side metallic layer 6 on the LED chip may be soldered to the metal part of the metal substrate 18 at the same time as the chip LED of the invention is implemented on the metal substrate 18. In this way, the LED module having the very good heat dissipation may be provided.

For the chip LED of the present invention, the glass epoxy resin-based substrate has the thermal expansion coefficient of 14-16×10⁻⁶. For the metal substrate 18 based on copper, it has the thermal expansion coefficient of 16.8×10⁻⁶, and for the substrate based on aluminum, it has the thermal expansion coefficient of 23×10⁻⁶. It may be recognized from the above that the difference in the thermal expansion coefficient between the chip LED of the present invention and the metal substrate 18 is very small, and the chip LED module having the structure described above has the strong and high reliability with respect to the temperature cycle.

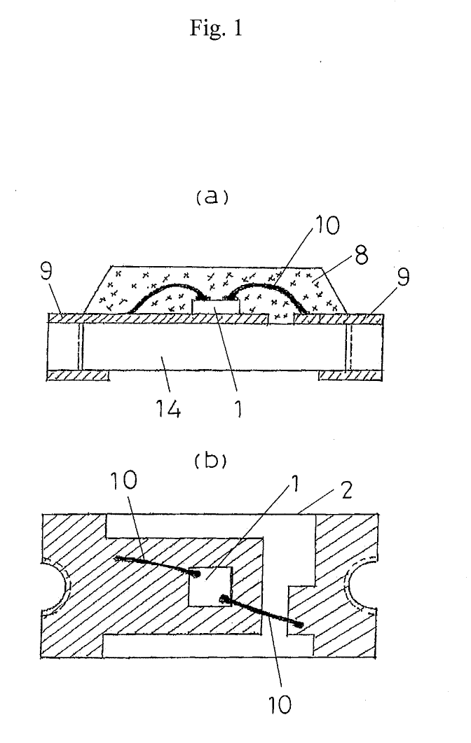

Now, the good thermal expansion coefficient provided by the chip LED of the present invention is described as it is compared with that of the conventional chip LED 3215 type shown in FIG. 1.

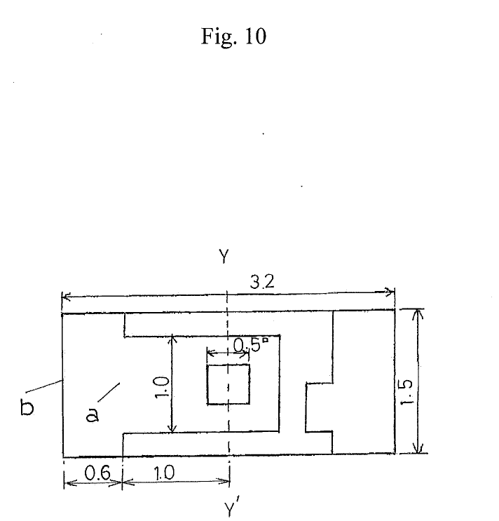

The LED 3215 type has the external dimensions as shown and described by using FIG. 10. In FIG. 10, the external dimensions and others are shown, with FIG. 1 (b) being omitted.

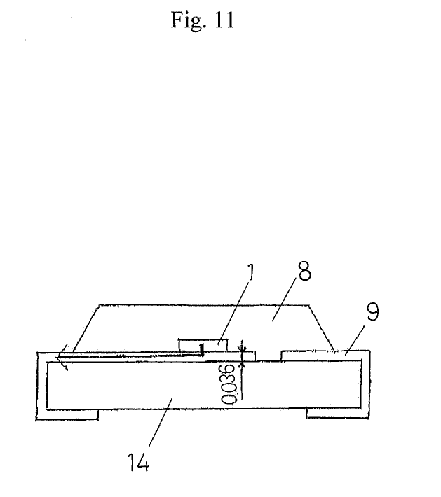

When the wiring pattern 9 has the dimensions as shown in FIG. 10, most of the heat produced from the LED chip 1 will be dissipated through the copper foil forming the wiring pattern 9. The LED chip 1 is surrounded by the copper foil-based wiring pattern 9, the sealing epoxy resin 8, and the glass epoxy resin-based substrate material 14. Upon comparing the thermal conductivity, it is found that the copper has the thermal conductivity of 398 W/mk, the epoxy resin has the thermal conductivity of 0.21 W/mk, and the glass epoxy resin has the thermal conductivity of 0.42 W/mk. In fact, most of the heat will thus be dissipated along the wiring pattern 9 as indicated by the arrow in FIG. 11.

For brevity, it is assumed that the center of the heating source is the center of the LED chip 1 (Y-Y′ line). Then, the heat dissipation, from which the heat dissipation of the sealing resin and glass epoxy resin is excluded, may be calculated as follow.

When the LED chip 1 on which the copper foil including the plated layer (wiring pattern 9) having the film thickness of 36 μm, 0.5 mm² is used and through which the current of 1 Watt power is made to flow, the difference between the temperature of the soldered point b and the temperature of the LED chip 1 will be equal to a+b=98.7° C.

The difference between the temperature of the center of LED chip 1 and the temperature of the point a will be equal to {1.0×10⁻³/{36×10⁻⁶×1.0×10⁻³}×1/398=69.8° C. The difference between the temperatures of the point a and point b will be equal to {0.6×10⁻³/(36×10⁻⁶×1.5×10⁻³)}×1/398=27.9° C.

With the chip LED of the present invention, the heat will flow through the copper foil (wiring pattern 9) as it is the case with that of the prior art. When the rear-side copper foil-based metallic layer 6 has the film thickness of 18 μm and the added plated layer has the film thickness of 18 μm, the copper foil including the plated layer will have the total film thickness of 36 μm as it is the case for that of the prior art.

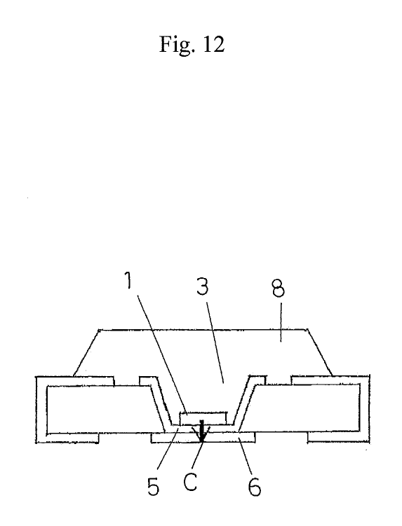

For the chip LED of the present invention, as the heat will flow through the right under of the copper foil die-bonded as indicated by the arrow in FIG. 12, the difference in the temperature between the center of chip LED and the soldered point c is as follow.

The difference in the temperature between the chip center and the point c is equal to {36×10⁻⁶/(0.5×0.5×10⁻⁶)}×1/398=0.36° C.

Assuming that the ambient temperature is 25° C., the temperature of the LED chip in the conventional commercial article will be equal to 97.7+25=122.7° C., whereas the temperature of the LED chip having the structure according to the present invention will be equal to 25+0.36=about 26° C.

The chip temperature may have the great effect on the lifetime and light-emitting efficiency of the LED. As it may also affect the light-emitting wavelength, the chip temperature will present a great problem when the backlight source is applied to the LCD television. It is also specified that the maximum junction temperature of the chip is set to approximately 120° C. For the conventional article that is commercially available, therefore, it may be concluded that the current of one-watt power cannot be made to flow.

The present invention provides the following advantages that are apparent from the foregoing description although they have been given as the approximate values.

For the actual LED chips, the heat is produced at the chip junction, and may be conducted through the path from the silver paste to the silver or gold plated layer and then to the nickel layer, then to the copper layer and finally to the copper foil. The temperature that occurs along the path may be rising slightly such as below 3° C. As described earlier, the heat that is dissipated through the sealing glass epoxy resin is also negligible. In this regard, therefore, the heat dissipation is not taken into account.

### Application To White Color LED

It is usual that the white color LED can provide the white color light by covering the blue color light-emitting element with the resin containing the phosphor material (Ref: Publication (2)).

Conventionally and usually, the epoxy resin is used as the sealing resin for the LED. It is noted, however, that the epoxy resin may be deteriorated by the blue color having the short wavelength and may thus be discolored, shortening its lifetime. Generally, therefore, the surface of the LED chip is covered with the silicone resin that is hard to be discolored.

For the chip LED having the conventional structure, however, it may be appreciated that when the LED chip is previously covered with the silicone resin, the silicone resin tends to flow and expand, making it difficult to use the LED chip.

Conventionally, therefore, the epoxy resin that contains the phosphor material mixed with it has been used. In order to avoid that the resin is discolored by the short wavelength of the blue color, it can only be applied to the LED that has the small power and low light intensity (Ref: Publication (3)).

For the chip LED of the present invention, as shown in FIG. 3, the LED chip 1 may be covered by filling the recess 3 with the silicone resin 7 that is mixed with the phosphor material. Furthermore, it makes it possible to transfer-mold the epoxy resin. The problem of causing the resin to discolor the chip surface can be avoided in this way.

The surface of the metallic layer 5 on the recess 3 can be finished by the silver plating. Thus, the reflectivity to the short wavelength of the blue color can be improved, and the efficiency with which the light will be generated can be improved accordingly.

Furthermore, the reliability can be improved by the double-resin sealing, such as the epoxy resin 8 and the silicone resin 7. Specifically, the epoxy resin 8 is capable of absorbing the humidity, but it does not allow the humidity to be penetrated, whereas the silicone resin allows the humidity to be penetrated, but is not capable of absorbing the humidity. Those two resins have the merits and demerits, respectively. The demerits can be complemented by the merits of each other.

As described above, the silver plating has the problem in that the silver will react against the sulfur, causing it to be changed to the black color substance called as the sulfurized silver and causing the light intensity to be reduced considerably. When the sealing is performed by the silicone resin alone, there is also a problem that the silicone resin will admits the sulfurized gas by allowing it to be penetrated there through. Those problems can be eliminated by using the double sealing that consists of the epoxy resin and the silicone resin because the epoxy resin prevents the sulfurized gas from being penetrated through the silicone resin.

1-4. (canceled)

5. A chip LED comprising:
a glass epoxy resin-based packaging substrate having a rear-side copper foil-based metallic layer on a rear-side thereof; and
more than at least one semiconductor chips deposited on the packaging substrate, wherein at least one of the semiconductor chips is a blue color-emitting element;
a recess formed on the packaging substrate and being directed from a front side toward said rear side of the packaging substrate, said recess having a depth that is greater than a thickness of said blue color-emitting element and extending from the front side toward said rear-side copper foil-based metallic layer, and a metallic layer finished by silver plating on the bottom surface and inner wall surface of said recess;
said blue color-emitting element being die-bonded to said metallic layer formed on the bottom surface of said recess and being wire-bonded to a wiring pattern deposited on a surface of the packaging substrate;
said recess being filled with a silicone resin containing a phosphor material and having an outside thereof covered with an epoxy resin; and
said metallic layer formed on the bottom surface of said recess being electrically conducted to said rear-side copper foil-based metallic layer formed on the rear side of the packaging substrate, said rear-side copper foil-based metallic layer providing a heat dissipating path for allowing the heat produced at the blue color-emitting element to be dissipated therethrough.

6. An LED module including a metal substrate on which the chip LED according to claim 5 is implemented by a soldering process, and a metal portion on said metal substrate to which said rear-side metallic layer is bonded by the soldering process at the same time as said chip LED is implemented on the metal substrate.
